(19) United States
(12) Patent Application Publication
(10) Pub. No.: US 2011/0043217 A1
(43) Pub. Date: Feb. 24, 2011

(54) ELECTRODE FAULT DETECTION

(76) Inventors: Kostas Ioannis Tsampazis, North Ryde, NSW (AU); Andrew Saldanha, Lane Cove, NSW (AU); Riaan Rottier, Lane Cove, NSW (NL)

Correspondence Address: JOHN S. PRATT, ESQ. (Cochlear);KILPATRICK STOCKTON LLP, 1100 PEACHTREE STREET, SUITE 2800, ATLANTA, GA, 30309, US

(21) Appl. No.: 12/811,696

(22) PCT Filed: Jan. 2, 2009
(86) PCT No.: PCT/AU2009/000001

§ 371 Date: Nov. 5, 2010

(30) Foreign Application Priority Data
Jan. 2, 2008 (AU) 200890008

(51) Int. Cl. G01R 31/02

(52) U.S. Cl. 324/537

(57) ABSTRACT

A method for detecting an electrode fault in a cochlear prosthesis. A voltage between the implanted electrode and a reference node is measured. It is then determined whether the voltage measured has been affected by an electrical leakage path between the electrode and a power supply node.

### CROSS-REFERENCE TO RELATED APPLICATIONS

The present application is a National Stage Application of International Application No. PCT/AU2009/000001, filed on Jan. 2, 2009, entitled “Electrode Fault Detection,” which claims priority from Australian Patent Application No. Australian Provisional Patent Application No. 2008900008 filed on 2 Jan. 2008, the contents of which are hereby incorporated by reference herein.

### BACKGROUND

1. Field of the Invention

The present invention relates generally to cochlear implants, and in particular, to the in situ identification of electrode faults.

2. Related Art

Cochlear prostheses or cochlear implant systems bypass the hair cells in the cochlea and directly deliver electrical stimulation to the auditory nerve fibres, thereby allowing the brain to perceive a hearing sensation resembling the natural hearing sensation normally delivered to the auditory nerve. U.S. Pat. No. 4,532,930, provides a description of one type of cochlear implant system.

A cochlear prosthesis generally comprises several electrodes including for example a set of implanted intracochlea electrodes, and a number of implanted extracochlea electrodes such as a plate electrode on the body of the implanted receiver stimulator and/or a ball electrode spaced apart from the body of the implanted receiver stimulator.

It is to be expected that a cochlear implant recipient will occasionally be subjected to electrostatic shocks arising from wearing rubber shoes on synthetic carpets, contact with electrostatically charged objects such as cars, and so on. Cochlear implants usually have features to protect against the effects of electrostatic discharge (ESD), such as is disclosed in U.S. Pat. No. 5,584,870 by the present applicant. However, ESD may nevertheless damage one or more components of the prosthesis if the static electricity level is excessive. Electrodes may become faulty in this way or through other mechanisms, and such electrode faults will generally lead to sub-optimal device operation.

### SUMMARY

In one aspect of the present invention, a method for detecting an electrode fault in a cochlear prosthesis is disclosed. The method comprising: measuring a voltage between an implanted electrode and a reference node, anddetermining whether the measured voltage has been affected by an electrical leakage path between the implanted electrode and a power supply node.

In another aspect of the present invention, a method for detecting an electrode fault in a cochlear prosthesis is disclosed. The method comprising: in a first phase, establishing a first current flow path from a first node to a first implanted electrode, from the first implanted electrode through interposed tissue to a second implanted electrode, and from the second implanted electrode to a second node, and obtaining a first voltage measurement between the second implanted electrode and a reference node; in a second phase, establishing a second current flow path from the first node to the second implanted electrode, from the second implanted electrode through interposed tissue to the first implanted electrode, and from the first implanted electrode to the second node, and obtaining a second voltage measurement between the first implanted electrode and the reference node; and comparing the first voltage measurement with the second voltage measurement to detect the presence of a leakage path.

In a further aspect of the present invention, a method for detecting an electrode fault in a cochlear prosthesis is disclosed. The comprising: open circuiting an implanted electrode so that no current flow paths are provided through the implanted electrode; and measuring a voltage between the implanted electrode and at least one reference node to determine whether a leakage path between the implanted electrode and a power supply node exists.

### BRIEF DESCRIPTION OF THE DRAWINGS

An example of the invention will now be described with reference to the accompanying drawings, in which:

FIG. 1 is a pictorial representation of a cochlear implant system;

FIGS. 2a and 2b illustrate first and second phase measurements in the absence of any ESD fault;

FIGS. 3 a and 3b illustrate first and second phase measurements in the presence of an ESD fault causing a leakage path from the ball electrode to the V_{dd} supply;

FIGS. 4a and 4b illustrate first and second phase measurements in the presence of an ESD fault causing a leakage path from the ball electrode to the Vₛₛ supply;

FIG. 5 illustrates initial configuration of an open circuited electrode voltage telemetry technique for electrode fault detection in accordance with one embodiment of the third aspect of the present invention;

FIGS. 6a and 6b illustrate first and second open circuited electrode voltage measurements in the technique of FIG. 5;

FIGS. 7a and 7b illustrate the open circuited electrode voltage telemetry techniques of FIGS. 6a and 6b in the presence of an ESD fault causing a leakage path from the electrode to the Vₛₛ supply, and in the presence of an ESD fault causing a leakage path from the electrode to the V_{dd} supply, respectively;

FIG. 8 illustrates a circuit configuration during initial energization of stimulation circuitry in another embodiment of the third aspect of the invention;

FIG. 9 illustrates the circuit of FIG. 8 when configured for electrode voltage measurement, in accordance with certain embodiments of the present invention;

FIG. 10 illustrates the influence of any electrode faults on the configuration of FIG. 9; and

FIG. 11 illustrates electrode voltages arising from application of a four phase current pulse waveform delivered in another embodiment of the second and fifth aspects of the invention.

### DETAILED DESCRIPTION

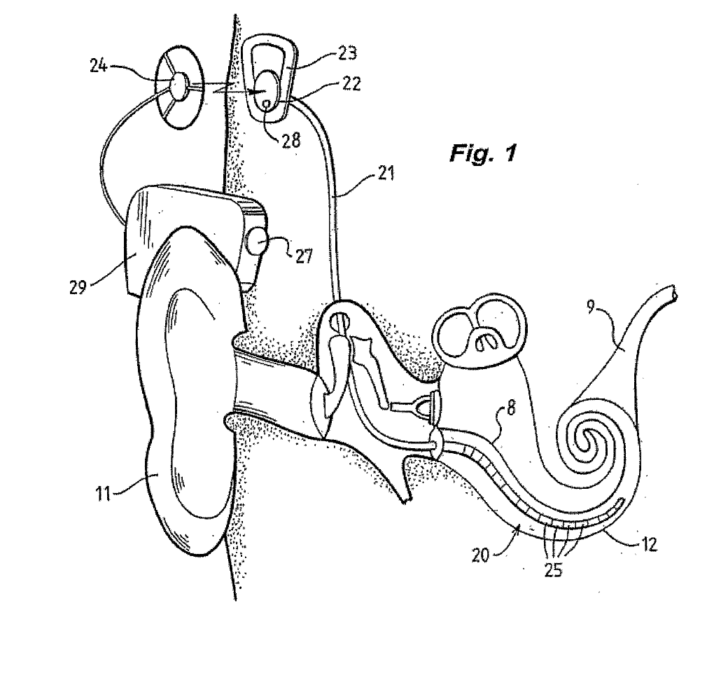

Before describing the features of the present invention, it is appropriate to briefly describe the construction of a cochlear implant system with reference to FIG. 1.

Cochlear implants typically consist of two main components, an external component including a sound processor 29, and an internal component including an implanted receiver and stimulator unit 22. The external component includes an on-board microphone 27. The sound processor 29 is, in this illustration, constructed and arranged so that it can fit behind the outer ear 11. Alternative versions may be worn on the body or it may be possible to provide a folly implantable system which incorporates the speech processor and the microphone into the implanted stimulator unit. Attached to the sound processor 29 is a transmitter coil 24 which transmits electrical signals to the implanted unit 22 via an RF link.

The implanted component includes a receiver coil 23 for receiving power and data from the transmitter coil 24. A cable 21 extends from the implanted receiver and stimulator unit 22 to the cochlea 12 and terminates in an electrode array 20. The signals thus received are applied by the array 20 to the basilar membrane 8 thereby stimulating the auditory nerve 9. The implanted component generally also includes a plate electrode 28 on the body of unit 22, and a ball electrode (not shown) mounted on a cable at a distance from the unit 22 and external to the cochlea 12. The operation of such a device is further described, for example, in U.S. Pat. No. 4,532,930.

The present invention provides for in vivo fault detection of such an implant's electrodes such as may be caused by electrostatic discharge (ESD). Preferred embodiments apply appropriate stimulation on two electrodes (on the two extracochlea electrodes, or on two intracochlea electrodes, or on one intracochlea electrode and one extracochlea electrode, for example) and undertake telemetry measurement of the electrode voltage on these electrodes. Comparing the measured electrode voltage values, an ESD fault of the implanted electrode can be identified.

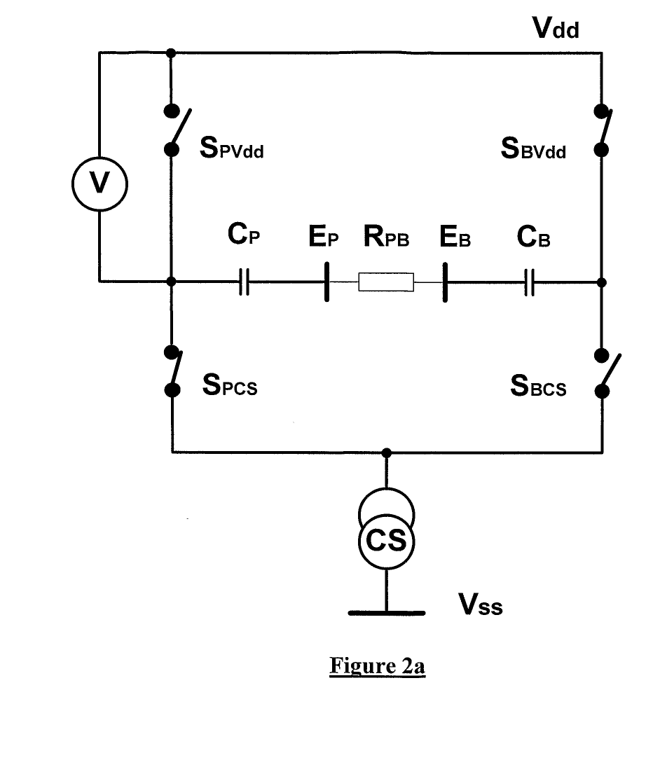

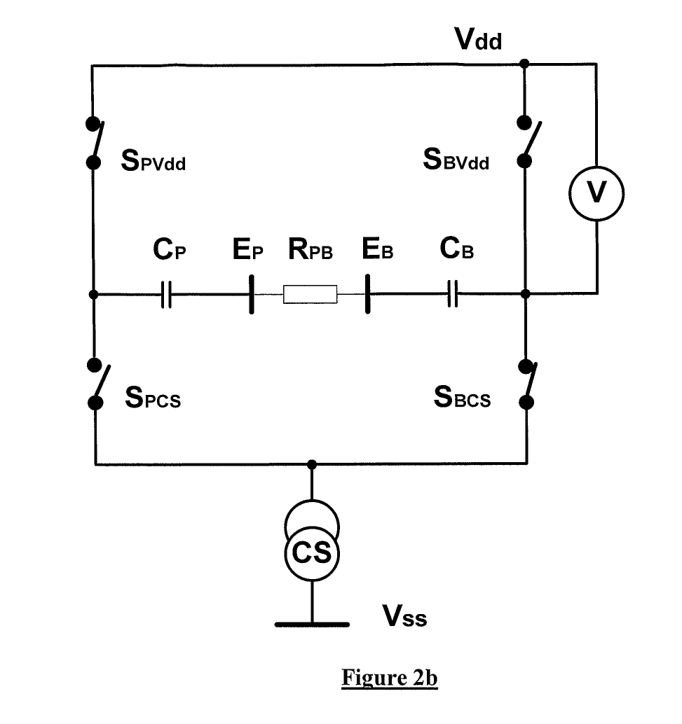

Most often, ESD damage occurs on one of the extracochlea electrodes (Plate or Ball electrode). The described method and circuitry for in vivo implant ESD fault detection is therefore based on appropriate stimulation on the two extracochlea electrodes however it is to be appreciated that the technique is also applicable to intracochlea electrodes. A simplified electrical diagram of the stimulation and measurement circuitry of a non faulty implant is shown in FIG. 2a (phase 1) and FIG. 2b (phase 2) where:

V_{dd} and Vₛₛ are the power supply rails or nodes

CS is the Current Source

Eₚ, E_{B} are the Plate and Ball electrodes respectively

Cₚ, C_{B} are the Plate electrode capacitor and the Ball electrode capacitor respectively

R_{PB} is the electrode, electrode/tissue and tissue impedance between the Plate and the Ball electrodes

S_{pvdd}, S_{Bvdd} are the Plate and Ball electrode switches to V_{dd}

S_{pcs}, S_{BCS} are the Plate and Ball electrode switches to the Current Source

V is the voltmeter circuitry

In this embodiment, telemetry measurement of the electrode voltage on the electrodes is referenced to V_{dd}, however in alternative embodiments the voltage measurements may be referenced to a different node. Comparing the measured electrode voltage values, an ESD fault of an electrode can be detected, because in the absence of any fault the stimulation and measurement circuitry is symmetrical during phase 1 and phase 2 as shown in FIGS. 2a and 2b. During phase 1 (FIG. 2a) the S_{Bvdd} and S_{pcs} switches are switched ON. The stimulation current flows from the V_{dd} power supply rail through the S_{Bvdd} switch, the Ball electrode capacitor C_{B}, the Ball electrode E_{B}, the electrode and tissue impedance between the Plate and the Ball electrodes R_{PB}, the Plate electrode E_{B}, the Plate electrode capacitor C_{P}, the S_{BCS} switch and through the Current Source CS to the Vₛₛ power supply rail. The voltage on the Plate electrode E_{B} is measured by the voltage measurement circuitry V.

During phase 2 (FIG. 2b) S_{Ppvdd} and S_{BCS} switches are switched ON. The stimulation current thus flows from the V_{dd} power supply rail through the S_{pvdd} switch, the Plate electrode capacitor Cₚ, the Plate electrode Eₚ, the electrode and tissue impedance between the Plate and the Ball electrodes R_{PB}, the Ball electrode E_{B}, the Ball electrode capacitor C_{B}, the S_{BCS} switch and through the Current Source Cₛ to the Vₛₛ power supply rail. The voltage on the Ball electrode E_{B} is measured by the voltage measurement circuitry V.

Due to the symmetry of the stimulation and measurement circuitry during phase 1 and phase 2, under normal conditions the measured Eₚ and E_{B} electrode voltages should have closely similar values, within a small deviation due to parasitic capacitance and electrode interface capacitance. To minimize the effect of the build up and reduction of charge in such capacitances during the two phases, the first voltage measurement is obtained at the beginning of phase 1 while the second voltage measurement is obtained at the end of phase 2. The voltage measurements are also preferably compensated for the presence of capacitive charge. The voltage distribution along the stimulation current circuitry/path in absolute value is the same regardless of the stimulation phase (phase 1 or phase 2).

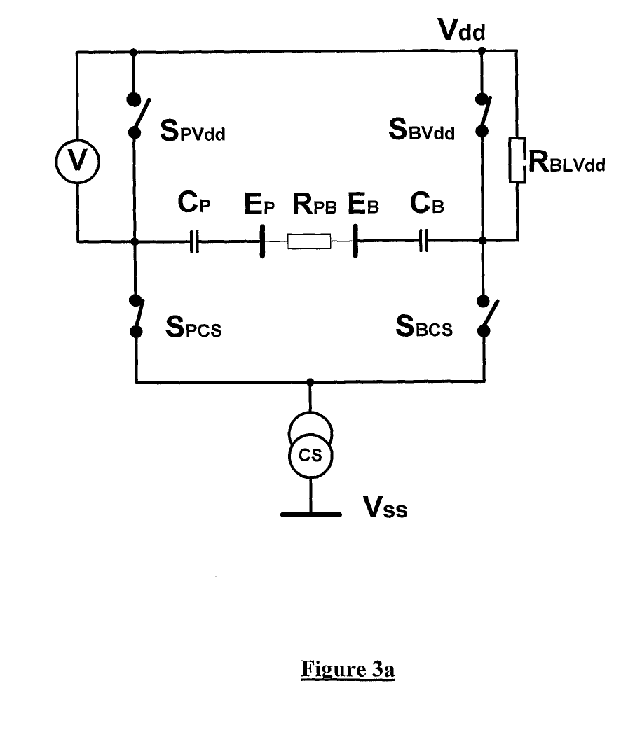

In case that the implant for example the Ball electrode has ESD damage, then a current leakage path between the Ball (the faulty) electrode and the V_{dd} (or Vₛₛ) power supply rail exists. FIG. 3a (phase 1) and FIG. 3b (phase 2) depict a Ball electrode E_{SD} fault with current leakage to V_{dd}, where:

R_{BLVdd} is the impedance of the leakage path between the Ball electrode and the V_{dd} power supply rail.

As can be seen, in the presence of a fault the phase 1 and phase 2 voltage measurements are no longer symmetrical, giving an indication of the existence of the fault.

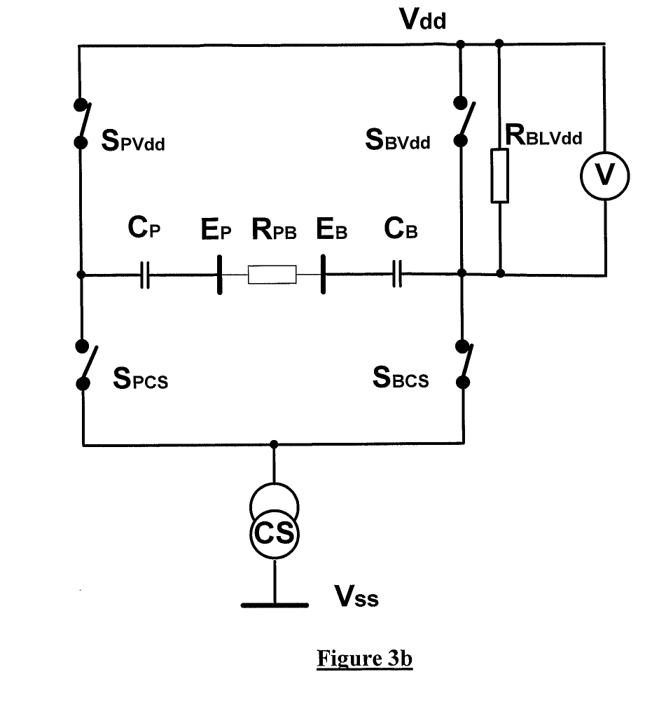

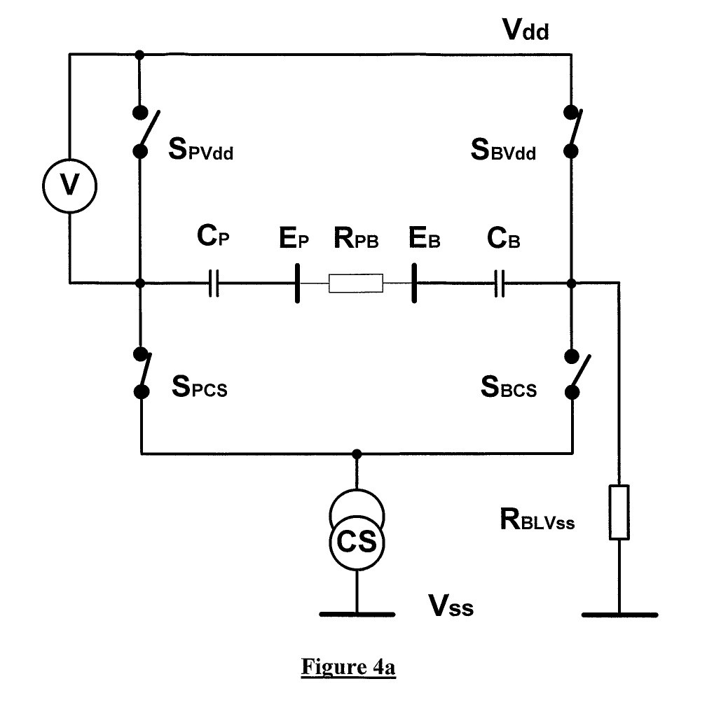

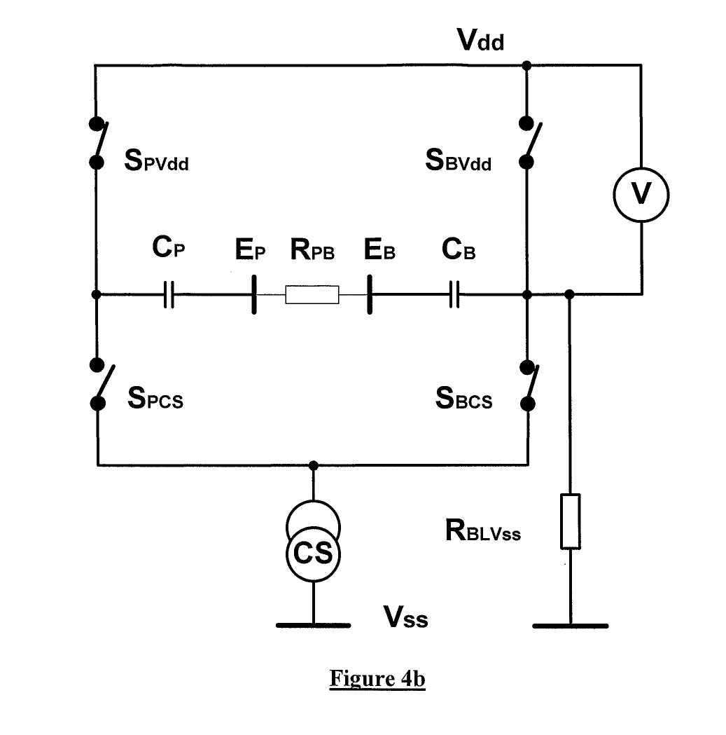

FIG. 4a (phase 1) and FIG. 4b (phase 2) depict a Ball electrode E_{SD} fault with current leakage to Vₛₛ, where:

R_{BLVSS} is the impedance of the leakage path between the Ball electrode and the Vₛₛ power supply rail.

Once again, in FIGS. 4a and 4b if such a fault exists the stimulation and measurement circuitry is not symmetrical during phase 1 and phase 2 and as a result, the measured E_{P} and E_{B} electrode voltages have different values. The leakage current path to V_{dd} (R_{BLVdd}) or to Vₛₛ (R_{BLVSS}) shunts the stimulation circuitry and additional leakage current flows through R_{BLVdd} or R_{BLVSS} resulting in different electrode voltages arising on Eₚ during phase 1 and on E_{B} during phase 2.

Suitable software is used to control and synchronize the switching of the voltage measurement circuitry (referenced to V_{dd}) as well as to calculate and display the results appropriately. In this embodiment, E_{SD} fault detection is thus based on appropriate stimulation of the two electrodes of interest (whether extracochlea electrodes and/or intracochlea electrodes), and measurement of the electrode voltage of the stimulation electrodes in each phase.

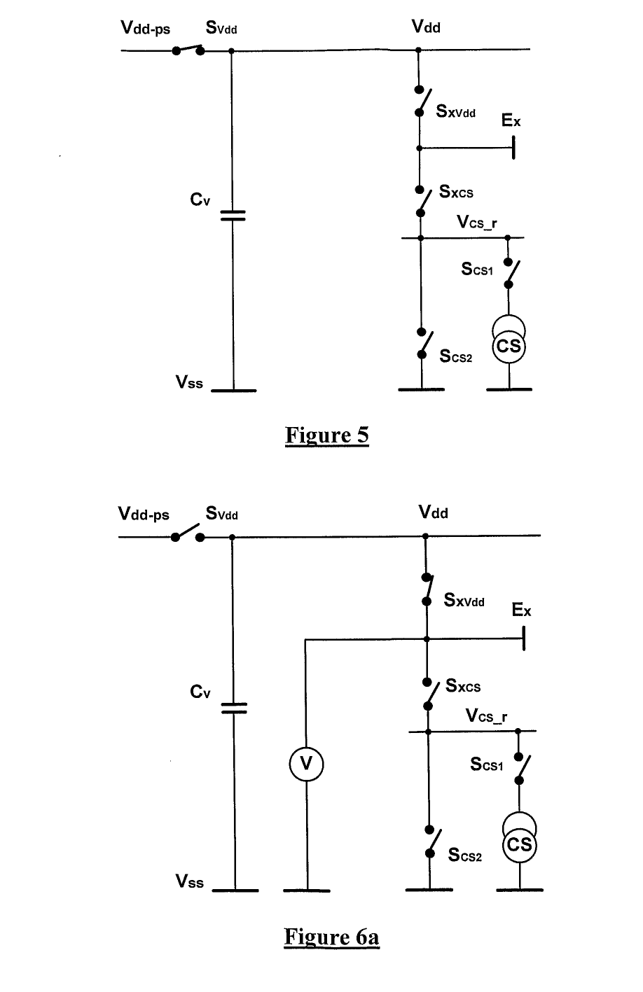

In another embodiment, voltage measurement circuitry may be applied, by connecting such circuitry to an intracochlea electrode or to an extracochlea electrode. This provides an alternative technique by which to identify an E_{SD} fault of an implant as shown in FIGS. 5 to 7. Initially the stimulation circuitry is powered without stimulation, as shown in FIG. 5. S_{vdd} is switched ON and all other switches (S_{xvdd}, S_{xcs}, S_{cs1} and S_{cs2}) are switched OFF. A capacitor Cᵥ between the positive power supply rail V_{dd} and the negative power supply rail Vₛₛ is thus charged up to the voltage level provided by _{Vdd-ps}.

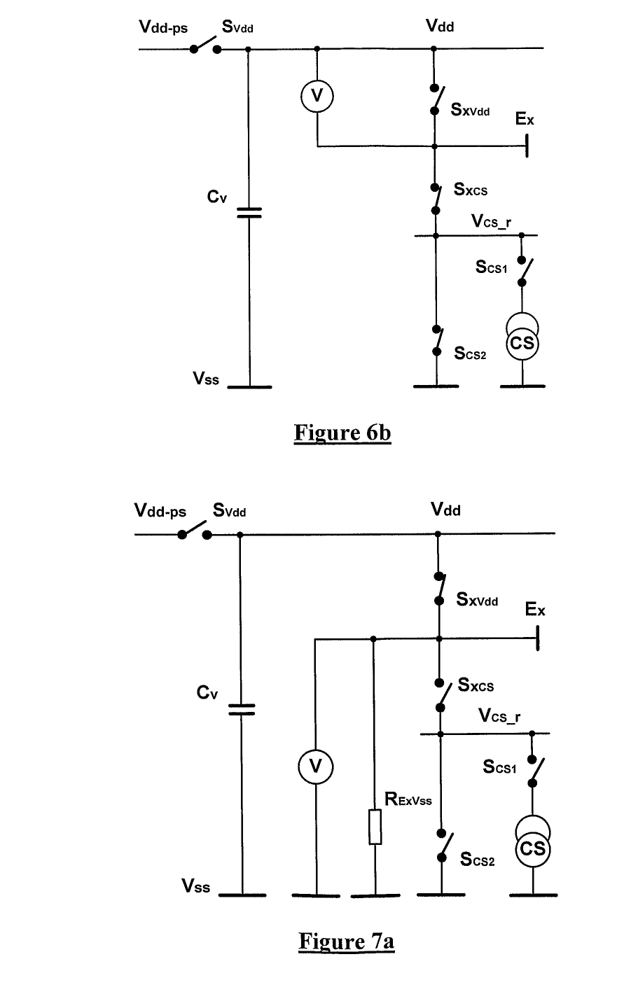

As shown in FIG. 6a, prior to the voltage measurement the switch S_{vdd} opens, so that the voltage over the capacitor Cᵥ powers the V_{dd} electrode power supply rail. This technique involves electrode voltage (potential) measurement (referenced for example to the V_{dd} rail or Vₛₛ rail) when the stimulation circuitry is powered by the voltage over a capacitor Cᵥ connected between V_{dd} and Vₛₛ and no stimulation is applied.

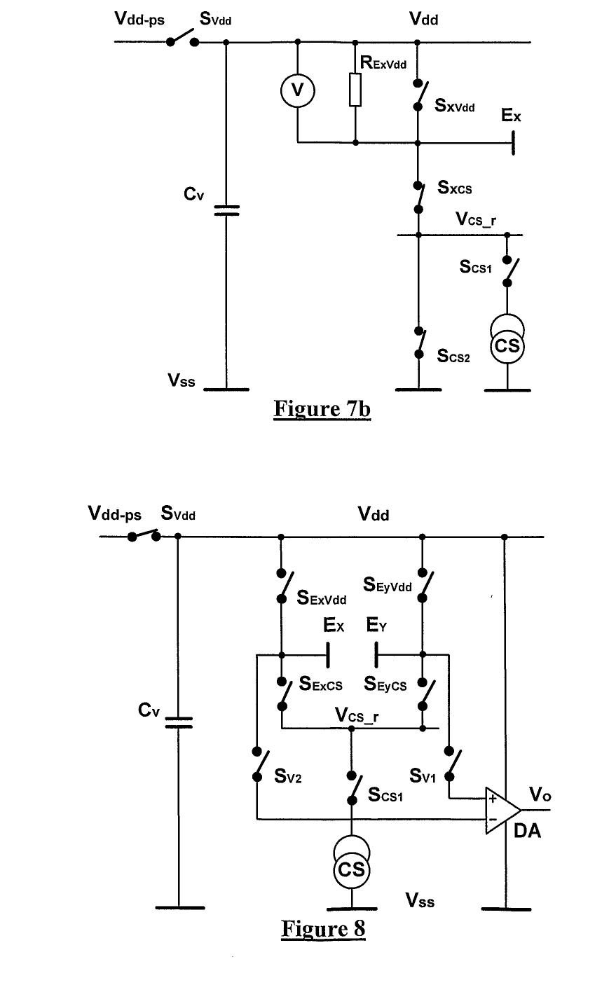

Referring to FIG. 6a, when the electrode is referenced (shorted) to the V_{dd} rail, the electrode voltage measured relative to Vₛₛ is constant provided no current leakage path from the electrode to the Vₛₛ rail exists. If a current leakage path from the electrode to the Vₛₛ rail exists due to an electrode fault, as illustrated in FIG. 7a, then the electrode voltage will decrease as the capacitor Cᵥ discharges through the current leakage path Rₑₓᵥₛₛ.

Similarly, referring to FIG. 6b, when the electrode is referenced to the Vₛₛ rail, the electrode voltage measured relative to V_{dd} is constant provided that no current leakage path from the electrode to the V_{dd} rail exists. If there is a current leakage path from the electrode to V_{dd} due to an electrode fault, as is illustrated in FIG. 7b, then the electrode voltage will decrease as the capacitor Cᵥ discharges through the current leakage path R_{EXVdd}.

The technique of FIGS. 5 to 7 thus provides for the voltage measurement to indicate the presence of an electrode fault. Furthermore, this technique allows knowledge to be obtained as to whether the fault presents as a leakage path from the electrode to V_{dd} or as a leakage path to Vₛₛ.

The circuit configuration shown in FIGS. 6a and 7a is used to detect current leakage to Vₛₛ. Switch S_{xvdd} is switched ON and switches S_{xcs} and S_{cs2} are switched OFF, causing the voltage on capacitor Cᵥ to be applied to the electrode Eₓ. If, as shown in FIG. 6a, there is no current leakage path from electrode Eₓ to Vₛₛ, then the electrode voltage measured to Vₛₛ by the voltmeter V is constant, as no current path for discharging the capacitor Cᵥ exists. On the other hand, if as shown in FIG. 7a there is a current leakage path R_{EXVSS} from electrode Eₓ to Vₛₛ, then the electrode voltage measured to Vₛₛ by the voltmeter V is not constant, as the capacitor Cᵥ discharges through R_{Exvss} and the electrode voltage will decrease. Consequently, the circuit configuration of FIGS. 6a and 7a enables diagnosis of whether there is an electrode fault between Eₓ and Vₛₛ.

Moreover, the circuit configuration shown in FIGS. 6b and 7b is able to detect current leakage from Eₓ to V_{dd}. In this configuration switches S_{xcs} and S_{cs2} are switched ON and switch S_{xvdd} is switched OFF, so that the electrode Eₓ is connected to the Vₛₛ rail. If, as is shown in FIG. 6b, there is no current leakage path from electrode Eₓ to V_{dd}, then the electrode voltage measured to V_{dd} by the voltmeter V is constant, as no current path discharging the capacitor Cᵥ exists. On the other hand, if as is shown in FIG. 7b there is a current leakage path R_{Exvdd} from electrode Eₓ to V_{dd} then the electrode voltage measured to V_{dd} by the voltmeter V is not constant, as the capacitor Cᵥ will discharge through R_{Exvdd} and the electrode voltage will decrease.

Noting that it is unknown whether a fault will produce a leakage path to V_{dd} or Vₛₛ, preferably the measurements depicted in FIGS. 7a and 7b are carried out sequentially in order to detect either type of fault. In alternative embodiments of the technique of FIGS. 6 and 7 the voltage measurement may be referenced to a reference node other than Vₛₛ or V_{dd}.

FIGS. 8 to 10 illustrate another embodiment of the third aspect of the invention, in which voltage measurements are made on two electrodes. FIG. 8 illustrates the circuit configuration during initial energizationof the stimulation circuitry. Initially, only the power supply switch S_{vdd} is switched ON and all other switches are switched OFF. As a result the power supply voltage V_{dd-ps} is applied to the V_{dd} rail, powering up the stimulation circuitry, and charging the capacitor Cᵥ to the power supply voltage value. A differential amplifier (DA) is powered from the voltage over the capacitor Cᵥ via the V_{dd} rail. The differential input of the DA is connected to electrodes Eₓ and E_{y} through the switches Sᵥ₁ and Sᵥ₂.

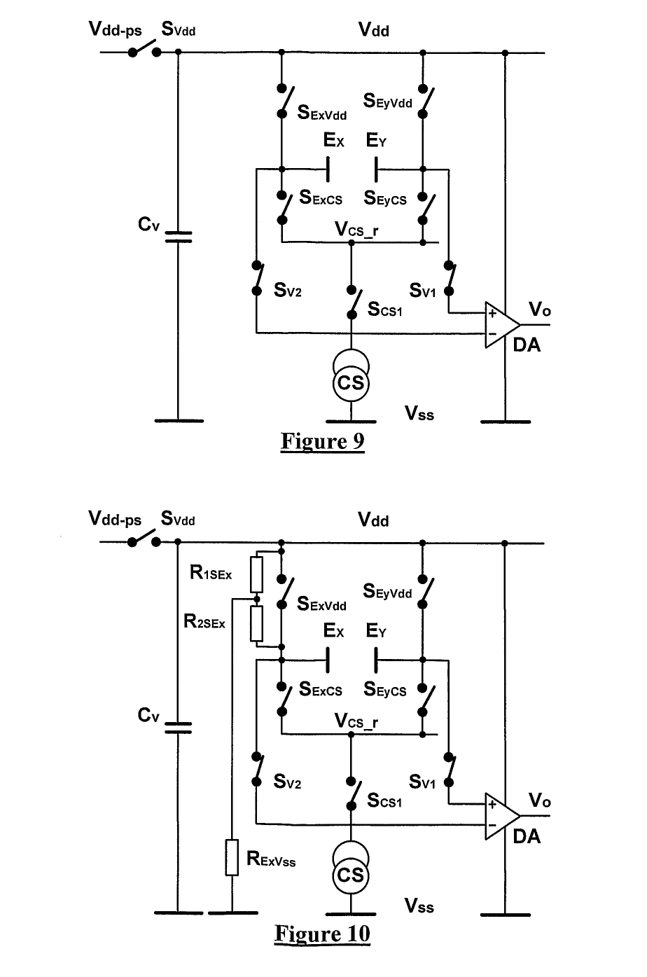

Once powered up, the circuit is then configured for electrode voltage measurement in the manner shown in FIG. 9. During the measurement, the S_{vdd} switch is switched OFF and Sᵥ₁ and Sᵥ₂ switches are switched ON. All electrode switches (S_{exvdd}, S_{excs}, S_{eyvdd}, S_{excs}) and the S_{cs1} switch are switched OFF, as no stimulation is required during the measurement. The voltage over the capacitor Cᵥ is applied to the electrodes' switches S_{exvdd} and S_{eyvdd} through the power supply rail V_{dd}.

If, as is shown in FIG. 9, there is no leakage current path from the V_{dd} rail through the electrodes' switches to Vₛₛ, then the voltage over the capacitor Cᵥ remains unchanged during the measurement. In this embodiment the duration of the measurement is approximately 3 ms. Hence the power supply voltage V_{dd} and the input potential of the differential amplifier (DA), being the Eₓ-E_{y} potential remain constant during the measurement. As a result the output voltage Vo of the DA also remains constant during the measurement. That is, if there is no leakage current path to Vₛₛ, then the output waveform Vo will be flat.

FIG. 10 illustrates the influence of an electrode fault on this configuration. If, as is shown, a leakage current path R_{exyss} to the Vₛₛ rail exists, for example due to faulty condition of the S_{exvdd} switch (R₁ₛₑₓ, R₂ₛₑₓ), then the capacitor Cᵥ discharges through the power supply rail V_{dd} and the leakage current path R₁ₛₑₓ Rₑₓᵥₛₛ during the measurement. As a result the potential Eₓ-E_{y} at the input of the differential amplifier (DA) will decrease during the measurement, and the power supply voltage of the DA will also decrease during the measurement. Consequently, the output voltage Vo of the DA will change during the measurement. That is, if there is a leakage current path to Vₛₛ, then the output waveform Vo will have a slew which is proportional to the amount of leakage current.

It is to be noted that the measurement configuration of FIGS. 8 to 10 is capable of detecting a current leakage to Vₛₛ at any electrode E_{N}, even if that electrode is not connected to the differential input of the differential amplifier (DA). This is because the effect of the current leakage to Vₛₛ on the input potential and the power supply voltage of the DA is the same, in that the capacitor Cᵥ discharges through the current leakage path.

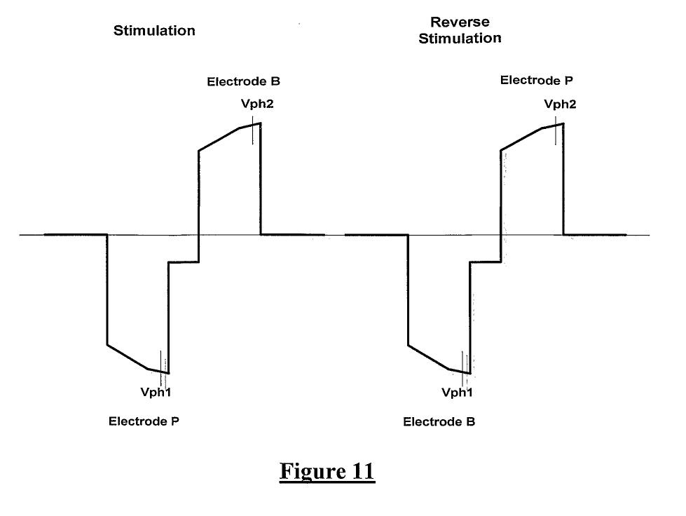

FIG. 11 shows electrode voltages arising from application of a four phase current pulse waveform delivered in another embodiment of the second and fifth aspects of the invention. In this embodiment, voltages are measured during stimulation on two electrodes. In this embodiment the two electrodes are the Plate electrode (P) and the Ball electrode (B), although alternative embodiments may apply this technique to other electrodes whether extracochlea and/or intracochlea. The voltage measurements obtained for electrode P (phase 1) and for electrode B (phase 2) are then compared. If no electrode fault exists at either electrode, then the current amplitude and, as a result, the electrodes' voltages measured will be substantially the same for both phases, allowing for some voltage offset of phase 2 due to electrode polarization during phase 1. That is, in the absence of any electrode fault there is no leakage to a power supply rail V_{dd} or Vₛₛ for both electrodes.

On the other hand, if an electrode fault exists then the electrode voltage for electrode P (phase 1) and electrode B (phase 2) will differ, as the current amplitude will be different for each phase as a consequence of current leakage to a power supply rail, V_{dd} or Vₛₛ.

To increase the sensitivity of the measurement and eliminate voltage offsets such as may be caused by electrode polarization during the first phase, this embodiment further involves stimulation and electrode voltage measurement in reverse electrode order. In this embodiment, a comparison is made of the measured amplitude of phase 1 of the first stimulation (the first voltage measurement) with the measured amplitude of phase 1 of the reverse stimulation (the third voltage measurement). Also, a comparison is made between the measured amplitude of phase 2 of the first stimulation (the second voltage measurement) and the measured amplitude of phase 2 of the reverse stimulation (the fourth voltage measurement).

This embodiment further provides for the electrode voltages Vₚₕ₁ and Vₚₕ₂ to be measured just before the end of the respective phase, at which time the voltage slope ΔV/Δt is at a minimum. It is to be appreciated that multiple measurements each phase could be obtained to facilitate more advanced data processing techniques to check for the presence of electrode faults. For example the average of 64 measurements of each phase could be used in order to increase accuracy and/or robustness. Repeated application of the balanced four phase method and averaging of each voltage measurement may also be applied to improve measurement robustness.

Advantages of these described methods include the capability of detecting ESD faults of implanted electrodes in vivo, and providing sensitivity to detect current leakage to V_{dd} and Vₛₛ for currents as small as 300 nA. Further, using a telemetry voltage measurement is advantageous in avoiding the need for any additional measurements to be taken by external devices in contact with the human body.

The proposed method can be used for self testing by a cochlear prosthesis. For example, the self test could be run automatically every time the implant is switched ON. In the event that a fault is detected, appropriate mitigation measures may be implemented, for example the faulty electrode can be switched OFF automatically and an adjacent operable electrode used instead.

Voltage telemetry measurements may be obtained for example in accordance with the teachings of International Patent Publication Nos. WO/2003/003791 and/or WO/1994/014376.

According to a first aspect the present invention provides a method for detecting an electrode fault in a cochlear prosthesis, the method comprising: measuring a voltage between an implanted electrode and a reference node, and determining whether the voltage measured has been affected by an electrical leakage path between the implanted electrode and a power supply node.

According to a second aspect the present invention provides a method for detecting an electrode fault in a cochlear prosthesis, the method comprising: in a first phase, establishing a current flow path from a first node to a first implanted electrode, from the first implanted electrode through interposed tissue to a second implanted electrode, and from the second implanted electrode to a second node, and obtaining a first voltage measurement between the second implanted electrode and a reference node; in a second phase, establishing a current flow path from the first node to the second implanted electrode, from the second implanted electrode through interposed tissue to the first implanted electrode, and from the first implanted electrode to the second node, and obtaining a second voltage measurement between the first implanted electrode and the reference node; and comparing the first voltage measurement and second voltage measurement to detect the presence of a leakage path.

According to a third aspect the present invention provides a method for detecting an electrode fault in a cochlear prosthesis, the method comprising: open circuiting an implanted electrode so that no current flow paths are provided through the implanted electrode; and measuring a voltage between the implanted electrode and at least one reference node to determine whether a leakage path between the implanted electrode and a power supply node exists.

According to a fourth aspect the present invention provides a computer program product comprising computer program code means to make a cochlear prosthesis execute a procedure for detecting an electrode fault of the cochlear prosthesis, the computer program product comprising: computer program code means for measuring a voltage between an implanted electrode and a reference node; and computer program code means for determining whether the voltage measured has been affected by an electrical leakage path between the implanted electrode and a power supply node.

According to a fifth aspect the present invention provides computer program product comprising computer program code means to make a cochlear prosthesis execute a procedure for detecting an electrode fault in the cochlear prosthesis, the computer program product comprising: computer program code means for, in a first phase, establishing a current flow path from a first node to a first implanted electrode, from the first implanted electrode through interposed tissue to a second implanted electrode, and from the second implanted electrode to a second node, and obtaining a first voltage measurement between the second implanted electrode and a reference node; computer program code means for, in a second phase, establishing a current flow path from the first node to the second implanted electrode, from the second implanted electrode through interposed tissue to the first implanted electrode, and from the first implanted electrode to the second node, and obtaining a second voltage measurement between the first implanted electrode and the reference node; and computer program code means for comparing the first voltage measurement with the second voltage measurement for indications of an electrode fault.

According to a sixth aspect the present invention provides a computer program product comprising computer program code means to make a cochlear prosthesis execute a procedure for detecting an electrode fault in the cochlear prosthesis, the computer program product comprising: computer program code means for open circuiting an implanted electrode so that no current flow paths are provided through the implanted electrode; and computer program code means for measuring a voltage between the implanted electrode and a reference node to determine whether an electrode fault has caused a leakage path between the implanted electrode and a power supply node.

The present invention thus recognizes that, following implantation, there is a need to determine the actual performance of the implanted electrodes and to identify any faults which may have occurred. This can enable confirmation of normal operation of the device, or enable faults to be detected and steps to be taken to compensate for such faults. The present invention further recognizes that damage to an implanted electrode manifests as an electrical leakage path from the electrode to a power supply node. By configuring the voltage telemetry measurements of the second and fifth aspects of the present invention in a manner that such a leakage path arising in only one of the two electrodes leads to an asymmetry between the first and second phase measurements, such a technique provides for the fault to affect only one measurement phase. Thus, the fault can be identified and measured by comparison to the other measurement phase. Similarly, by establishing an open circuited condition for the voltage measurement in the third and sixth aspects of the invention, such measurements enable an electrode fault leakage path to be detected.

Embodiments of the present invention thus provide a means and method for in vivo (in situ) detection of an implanted electrode fault which manifests as a leakage path from the electrode to a node of the power supply. Moreover, such telemetry techniques may enable detection of leakage currents as small as 300 nA for example, and advantageously do not require any additional measurements to be taken by external devices in contact with the human body.

In embodiments of the second and fifth aspects of the invention, a first current pulse may be delivered along the current flow path established in the first phase, and a second current pulse may be delivered along the current flow path established in the second phase. The first current pulse and the second current pulse are preferably of substantially the same magnitude and shape, such that tissue interposed between the first implanted electrode and the second implanted electrode receives a balanced biphasic pulsatile stimulus during the first and second phases.

In embodiments of the second and fifth aspects of the invention, the first phase may precede the second phase, or the second phase may precede the first phase. Further preferred embodiments of the invention may carry out the method with the first phase and second phase in a first order, and then repeat the method with the phases in reverse order. That is, such embodiments of the invention, referred to herein as a balanced four phase method, preferably comprise: performing the second phase after the first phase; in a third phase following the second phase, establishing a current flow path from the first node to the second implanted electrode, from the second implanted electrode through interposed tissue to the first implanted electrode, and from the first implanted electrode to the second node, and obtaining a third voltage measurement between the first implanted electrode and the reference node; in a fourth phase following the third phase, establishing a current flow path from the first node to the first implanted electrode, from the first implanted electrode through interposed tissue to the second implanted electrode, and from the second implanted electrode to the second node, and obtaining a fourth voltage measurement between the second implanted electrode and the reference node; and comparing the magnitudes of at least two of the first to fourth voltages.

Such embodiments of the invention, which repeat the method with transposed current pulse polarity to effect a balanced four phase method, may assist in minimizing the effects of voltage offsets which may occur between the first phase and the second phase and may occur between the third phase and the fourth phase. Such voltage offsets may for example be caused by electrode polarization arising from the first and third phases. Embodiments employing a balanced four phase method may thus improve sensitivity of the method to the presence of electrode faults.

In embodiments of the invention employing such a balanced four phase method, preferably the first voltage measurement is compared with the third voltage measurement for indications of whether an electrode fault exists. Such embodiments are advantageous because the first and third voltage measurements are respectively obtained from the second and first electrodes, but are also obtained during respective phases which are each initiated in the absence of voltage offsets, thereby improving accuracy. In such embodiments, preferably the first voltage measurement is obtained immediately prior to the conclusion of the first phase, and preferably the third voltage measurement is obtained immediately prior to the conclusion of the third phase. Such embodiments recognize that electrode voltage is more settled toward the end of each stimulus phase, such that a voltage measurement obtained toward the end of the respective phase provides improved accuracy of the measurement.

Additionally or alternatively, embodiments utilizing a balanced four phase method may compare the second voltage measurement with the fourth voltage measurement for indications of whether an electrode fault exists. Such embodiments may be somewhat less accurate but may nevertheless be useful in some applications.

In embodiments of the balanced four phase method in which the first and third voltages are compared, the second and fourth voltage measurements may be superfluous, and it is to be appreciated that omission of the second and/or fourth voltage measurements is within the scope of the present invention. Similarly, in embodiments of the balanced four phase method in which the second and fourth voltages are compared, the first and third voltage measurements may be superfluous, and it is to be appreciated that omission of the first and third measurements is within the scope of the present invention.

In embodiments of the first to sixth embodiments of the invention, the reference node could be any of a V_{dd} power supply node, a Vₛₛ power supply node, or any other suitable voltage reference point. The method of the invention is preferably repeated for different reference nodes to ensure that varying types of electrode faults can be detected.

In embodiments of the third and sixth aspects of the invention, the power supply node is preferably capacitively energized such that a leakage path will drain the capacitance leading to a detectable voltage change. In such embodiments two electrodes may be open circuited, and a difference between the electrode voltages may be measured by a differential amplifier which is itself powered by the capacitively energized power supply node.

It is to be appreciated that throughout the description, discussions utilizing terms such as “processing” or “computing” or “calculating” or “determining” or “displaying” or the like, refer to the action and processes of a computer system, sound processor component, or similar electronic computing device, that manipulates and transforms data represented as physical (electronic) quantities within the computer system's registers and memories into other data similarly represented as physical quantities within the computer system memories or registers or other such information storage, transmission or display devices.

It will be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive.

1. A method for detecting an electrode fault in a cochlear prosthesis, the method comprising:
measuring a voltage between an implanted electrode and a reference node, and
determining whether the measured voltage has been affected by an electrical leakage path between the implanted electrode and a power supply node.

2. A method for detecting an electrode fault in a cochlear prosthesis, the method comprising:
in a first phase, establishing a first current flow path from a first node to a first implanted electrode, from the first implanted electrode through interposed tissue to a second implanted electrode, and from the second implanted electrode to a second node, and obtaining a first voltage measurement between the second implanted electrode and a reference node;
in a second phase, establishing a second current flow path from the first node to the second implanted electrode, from the second implanted electrode through interposed tissue to the first implanted electrode, and from the first implanted electrode to the second node, and obtaining a second voltage measurement between the first implanted electrode and the reference node; and
comparing the first voltage measurement with the second voltage measurement to detect the presence of a leakage path.

3. The method of claim 2, wherein the first node is a power supply rail and the second node is a current source.

4. The method of claim 2, further comprising:
compensating at least one of the first and second voltage measurements to allow for inserted charge.

5. The method of claim 2, wherein the first phase precedes the second phase.

6. The method of claim 2, wherein a first current pulse is delivered along the first current flow path, and a second current pulse is delivered along the second current flow path, and wherein the first current pulse and the second current pulse are of substantially the same magnitude and shape.

7. The method of claim 2, further comprising:
in a third phase following the second phase, establishing a third current flow path from the first node to the second implanted electrode, from the second implanted electrode through interposed tissue to the first implanted electrode, and from the first implanted electrode to the second node, and obtaining a third voltage measurement between the first implanted electrode and the reference node;
in a fourth phase following the third phase, establishing a fourth current flow path from the first node to the first implanted electrode, from the first implanted electrode through interposed tissue to the second implanted electrode, and from the second implanted electrode to the second node, and obtaining a fourth voltage measurement between the second implanted electrode and the reference node; and
comparing the magnitudes of at least two of the first to fourth voltages.

8. The method of claim 7, further comprising:
obtaining each voltage measurement at a time during the respective phase at which a voltage slope is minimum.

9. The method of claim 7, wherein comparing the magnitudes of at least two of the first to fourth voltages comprises:
comparing the first voltage measurement with the third voltage measurement for indications of whether an electrode fault exists.

10. The method of claim 7, wherein comparing the magnitudes of at least two of the first to fourth voltages comprises:
comparing the second voltage measurement with the fourth voltage measurement for indications of whether an electrode fault exists.

11. The method of claim 2, wherein the reference node is one of:
a V_{dd} power supply node;
a Vₛₛ power supply node; and
an independent voltage reference point.

12. A method for detecting an electrode fault in a cochlear prosthesis, the method comprising:
open circuiting an implanted electrode so that no current flow paths are provided through the implanted electrode; and
measuring a voltage between the implanted electrode and at least one reference node to determine whether a leakage path between the implanted electrode and a power supply node exists.

13. The method of claim 12, further comprising:
capacitively energizing the power supply node such that a leakage path will drain the capacitance leading to a detectable voltage change.

14. The method of claim 13, further comprising:
open circuiting two electrodes, and
measuring a difference between the electrode voltages with a differential amplifier powered by the capacitively energized power supply node.

15.-17. (canceled)
